(19) United States
(12) Patent Application Publication
(10) Pub. No.: US 2006/0019471 A1
(43) Pub. Date: Jan. 26, 2006

(54) Method for forming silicide nanowire

(75) Inventor: Chel-jong Choi, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG ELECTRONICS CO., LTD., Suwon-si (KR)

(21) Appl. No.: 11/100,477

(22) Filed: Apr. 7, 2005

(30) Foreign Application Priority Data
Jul. 21, 2004 (KR) 10-2004-0056819

(51) Int. Cl. H01L 21/20; C23C 16/54; H01L 21/324

(52) U.S. Cl. 438/486; 438/484; 438/487; 438/795

(57) ABSTRACT

Methods for forming a silicon-based material layer are disclosed along with silicon-based material layers formed by the method and devices incorporating the silicon-based material layer. The method includes forming an amorphous layer on a silicon-based substrate, doping at least a region of the amorphous layer with a metal ion, and crystallizing the amorphous layer to form a plurality of crystal grains, wherein a grain boundary is between adjacent crystal grains and metal silicide is formed at the grain boundary. The formed metal silicide has nanowire dimensions.

### CROSS-REFERENCE TO RELATED APPLICATIONS

This application claims priority to and the benefits under 35 U.S.C §119 and/or § 365 to Korean Patent Application No. 2004-56819, filed on Jul. 21, 2004, the entire disclosure of which is herein incorporated by reference.

### FIELD OF THE DISCLOSURE

The present disclosure generally relates to metal silicides. More specifically, the present disclosure relates to wires of metal silicides, particularly nanoscale wires of metal silicides, and methods for preparing wires of metal silicides and uses of wire metal silicides in applications, such as field emitters and semiconductor memory devices.

### STATE OF THE ART

In the discussion of the state of the art that follows, reference is made to certain structures and/or methods. However, the following references should not be construed as an admission that these structures and/or methods constitute prior art. Applicant expressly reserves the right to demonstrate that such structures and/or methods do not qualify as prior art against the present invention.

Silicide is the reaction product of a metal and silicon. Conventionally, silicides are formed by depositing a metal on the silicon and annealing the structure, for example by rapid thermal annealing (RTA), flash annealing (FA) or laser techniques, to form a layered silicide formation. For example, U.S. Pat. No. 6,387,803 B2 discloses laser annealing a structure of a metal silicide layer on an amorphous silicon layer supported on a substrate. After laser annealing, the metal and amorphous silicon forms silicide on the substrate. In another example, U.S. Pat. No. 6,156,654 discloses titanium metal on a silicon substrate. This structure is processed by rapid thermal processing to form a layer of C49 TiSi₂ on the silicon substrate, which is subsequently processed by rapid thermal processing to form a continuous C54 TiSi₂ silicon substrate structure.

Typically, silicides have a low sheet resistance and a low contact resistance, which has resulted in their use in electronics applications.

A conventional silicide is generally used as means for reducing a surface resistance and a contact resistance of the contact regions inside a semiconductor device, for example. Examples of such uses include the contact regions of a gate, a source and a drain of the MOSFET, in which a metal silicide layer, a reaction resultant layer of silicon and metal, is formed on contact regions in order to reduce a surface resistance and a contact resistance with the contact regions. The technology of the formation of the metal silicide is generally limited to the technologies of forming layer type metal silicide.

### SUMMARY

A Si based material layer having a nanoscale of wire type silicide, and a formation method thereof for providing good field emission characteristics and good conductibility characteristics is provided.

In one exemplary embodiment, a Si based material layer includes a plurality of grains, and a metal silicide is formed at the grain boundary.

In another exemplary embodiment, a method of forming an Si based material layer includes forming an amorphous layer having a predetermined thickness on an Si based substrate, doping the amorphous layer with metal ions, and annealing the metal ion-doped amorphous layer, where annealing includes crystallizing the metal ion-doped amorphous layer to a polycrystalline layer including a plurality of grains, and forming metal silicide at the grain boundary

An exemplary method for forming a silicon-based material layer comprises forming an amorphous layer on a silicon-based substrate, doping at least a region of the amorphous layer with a metal ion, and crystallizing the amorphous layer to form a plurality of crystal grains, wherein a grain boundary is between adjacent crystal grains and metal silicide is formed at the grain boundary.

An exemplary embodiment of a silicon-based material layer, comprises a plurality of crystal grains in a silicon-based material and metal silicide, wherein the metal silicide is located within the silicon-based material layer at grain-boundaries between the plurality of crystal grains.

An exemplary embodiment of field emitter comprises a silicon-based substrate, a silicon-based material layer in direct contact with a first side of the silicon-based substrate, wherein the silicon-based material layer includes a plurality of crystal grains in a silicon-based material, and metal silicide, the metal silicide located within the silicon-based material layer at grain-boundaries between the plurality of crystal grains and the metal silicide is arranged in a continuous electrical conduction path along any one of the grain-boundaries from a surface of the silicon-based material layer to an interior position within the silicon-based material layer, a first electrode spaced apart from a surface of the silicon-based material by a spacer, and a second electrode on a second side of the silicon-based substrate.

### BRIEF DESCRIPTION OF THE DRAWING FIGURES

The following detailed description of preferred embodiments can be read in connection with the accompanying drawings in which like numerals designate like elements and in which:

FIGS. 1A to 1D broadly illustrate the process steps in an exemplary embodiment to form silicide nanowires.

FIGS. 2A to 2D broadly illustrate in an exemplary crosssectional view the position and movement of metal silicide in a silicon-based substrate as the substrate changes from amorphous to crystalline.

FIGS. 3A to 3D broadly illustrate in an exemplary plan schematic view the position and movement of metal silicide in a silicon-based substrate as the substrate changes from amorphous to crystalline.

FIG. 4 shows a schematic representation of an exemplary field emitter device.

FIG. 5 is a transmission electron microscope (TEM) image of a sample of a silicon substrate with an amorphous silicon layer with implanted nickel ions in Example 1. The inset shows x-ray diffraction for the shown sample.

FIG. 6 is TRIM simulation data for showing a number of ions per angstrom per implanted ion as a function of depth (in angstroms) for the sample shown in FIG. 5.

FIG. 7 illustrates x-ray photon spectroscopy-(XPS) graphs on samples of Example 1.

FIGS. 8A and 8B show scanning transmission electron microscopy (STEM) images for a sample of a polycrystalline silicon layer with embedded silicide nanowires formed at the grain boundaries of the polycrystalline silicon layer in Example 1.

FIG. 9A is a cross sectional STEM image and FIG. 9B is an energy dispersive x-ray spectroscopy (EDX) graph on a sample of Example 1.

FIG. 10A is a cross sectional STEM image and FIG. 10B is EDX graph on a sample of Example 1.

FIG. 11 is a plan STEM image showing a sample of a polycrystalline silicon layer with embedded silicide nanowires formed at the grain boundaries of the polycrystalline silicon layer in Example 2.

FIGS. 12A and 12B show Fowler-Nordheim graphs measured from a sample of Example 2.

### DETAILED DESCRIPTION

The present disclosure is directed generally to a method for forming a silicon-based material layer. In an exemplary embodiment, the method comprises forming an amorphous layer on a silicon-based substrate, doping at least a region of the amorphous layer with a metal ion and crystallizing the amorphous layer to form a plurality of crystal grains, wherein a grain boundary is between adjacent crystal grains and metal suicide is formed at the grain boundary.

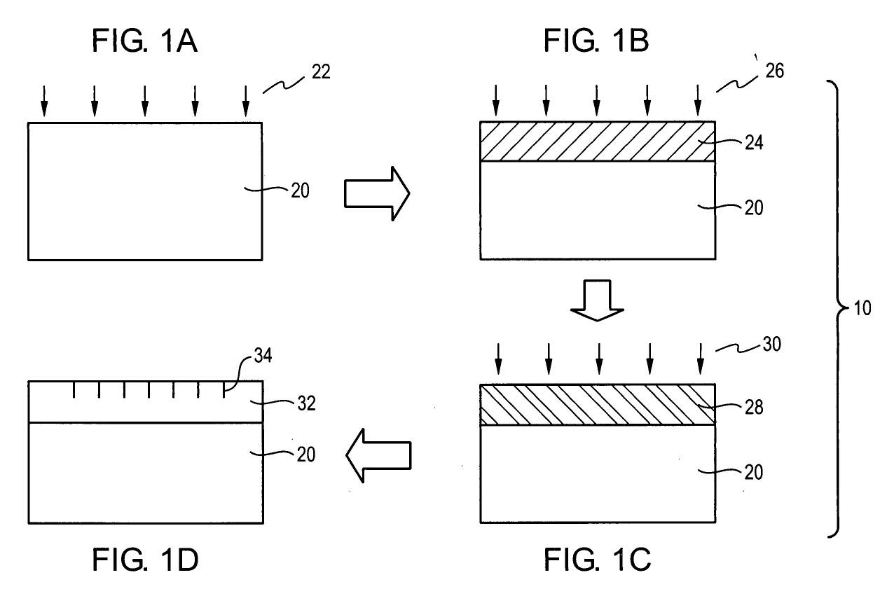

FIGS. 1A to 1D broadly illustrate the process steps in an exemplary embodiment of a method to form silicide nanowires. In the illustrated process steps 10, a silicon-based substrate 20 is implanted 22 with a group IV atom, such as a silicon atom, to form an amorphous layer 24. Subsequently, a metal ion, such as a nickel ion, is implanted 26 in the amorphous layer 24 to form a doped amorphous layer 28. The doped amorphous layer 28 is annealed 30 to crystallize the doped amorphous layer 28 forming a plurality of crystal grains. Within the crystallized doped layer 32, the implanted metal ions form a metal silidide 34. The metal silicide 34 may be formed with a predetermined depth from the surface of the doped amorphous layer into the interior, e.g., downward or in the vertical direction. The metal silicide 34 formed as above is not limited to the presence only in the vertical direction, but can be formed in the sloping direction from the surface with a depth determined by the doping parameters. In an exemplary embodiment, the metal silicide 34 is concentrated at the grain boundaries between adjacent grains of the crystallized doped layer 32. The formed metal silicide 34 may be more stably at the triple point of the grain boundary, and the formation can be controlled by annealing or metal ion doping parameters (e.g., concentration, energy, doping material and so forth).

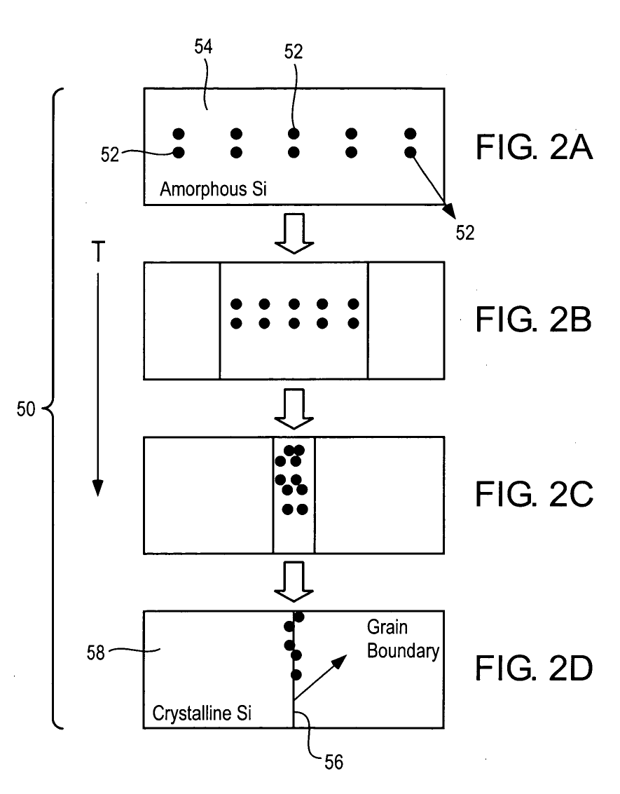

FIGS. 2A to 2D broadly illustrate in an exemplary schematic crosssectional view the position and movement of metal silicide in a silicon-based substrate as the substrate changes from amorphous to crystalline. In the FIGS. 2A to 2D embodiments 50, metal suicide 52 is shown within a matrix of amorphous material 54, such as amorphous silicon. As indicated in FIGS. 2A to 2D, temperature T is increased from FIG. 2A to FIG. 2D. As the temperature is increased, the metal silicide 52 agglomerates towards defined locations within the amorphous material 54. These defined locations can include grain boundaries 56, as the amorphous material 54 becomes crystalline over time at increasing temperature to form grains. Finally, after suitable time and at suitable temperature, the metal silicide 52 populates the grain boundaries 56 of the formed crystalline layer 58, such as a formed crystalline silicon layer.

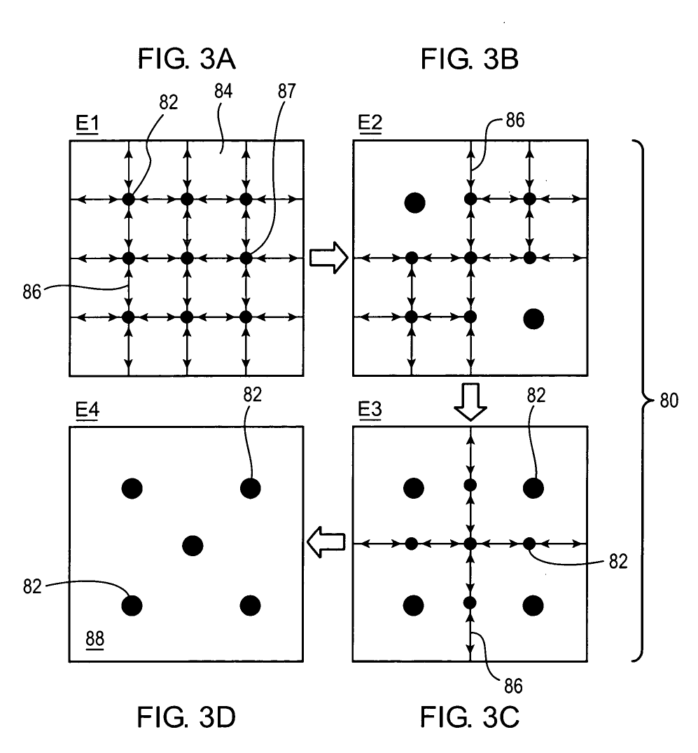

FIGS. 3A to 3D broadly illustrate in an exemplary plan schematic view the position and movement of metal silicide in a silicon-based substrate as the substrate changes from amorphous to crystalline. In the FIGS. 3A to 3D embodiments 80, metal silicide 82 is shown within a matrix of amorphous material 84, such as amorphous silicon. The energy density, e.g., the energy density of a laser directed to impinge the surface of the amorphous material 84, is increased from FIG. 3A to FIG. 3D, as illustrated by E₁<E₂<E₃<E₄. As energy density is increased, the metal silicide 82 agglomerates towards defined locations within the amorphous material 84 as the amorphous material 84 becomes crystalline over time at increasing energy density to form grains. Examples of these defined locations include grain boundaries. The arrows 86 imply movement of the metal silicide 82 as it agglomerates at the grain boundaries. This movement is influenced by the increasing energy density, E1 to E4. Finally, after suitable time and suitable energy density, the metal silicide 82 populates the grain boundaries of the formed crystalline layer 88, such as a formed crystalline silicon layer.

The amorphous layer can be formed in the substrate by any suitable means. For example, in the FIG. 1 embodiment, a group IV atom, such as a silicon ion, can be implanted in a silicon-based substrate to produce an amorphous layer, such as an amorphous silicon layer. Suitable silicon-based substrates include Si, SiGe, SiC, SiO₂, or SiO₂ with a layer of Si, SiGe or SiC on a first surface, MgO with a layer of Si, SiGe or SiC on a first surface, ITO with a layer of Si, SiGe or SiC on the a surface, crystalline Si with a layer of Si, SiGe or SiC on a first surface or amorphous silicon with a layer of Si, SiGe or SiC on a first surface. In an exemplary embodiment, implantation can be by a room temperature process under a vacuum. Other suitable means for forming an amorphous layer can also be used, such as sputter depositing a material, such as silicon, on to a single crystal substrate, such as single crystal silicon. The amorphous layer can be formed to any desired depth and can be accomplished by multiple steps or a single step, e.g., multiple discreet silicon ion implantation steps. For example, multiple ion implantation steps can be used to form homogenous implantation. When using ion implantation techniques, one of ordinary skill in the art would understand selecting parameters suitable to achieve a desired thickness of amorphous layer, e.g., 100 nm. However, it is presently contemplated that implantation energies between 1 keV and 1000 keV, preferably implantation energies above 50 keV, are used, although different energies produce different depths of implantation and different thickness of amorphous layers. For example, a preferred doping concentration or dose of the metal ion is from 1×10¹⁰ atom/cm² to 1×10¹⁷ atom/cm² and has a doping energy of 1 keV to 1000 keV. The silicon ion implantation can be at any location on the substrate surface, and can be over an entire substrate or masking techniques can be utilized.

Any Group IV atom can be used in the methods and devices disclosed herein. However, in some exemplary embodiments, the group IV atom is a carbon (C), silicon (Si), germanium (Ge), tin (Sn), or lead (Pb) atom or mixtures thereof. Further, exemplary metal ions for doping are selected from the group consisting of silver (Ag), gold (Au), aluminum (Al), copper (Cu), chromium (Cr), cobalt (Co), nickel (Ni), titanium (Ti), antimony (Sb), vanadium (V), molybdenum (Mo), tantalum (Ta), niobium (Nb), ruthenium (Ru), tungsten (W), platinum (Pt), palladium (Pd), zinc (Zn), and magnesium (Mg) or mixtures thereof, preferably a transition metal such as Ni, Ti, Cu, Co, Cr and mixtures thereof.

Doped metal ion implantation, such as nickel metal ion implantation, can be at an energy resulting in an implantation depth less than the thickness of the amorphous silicon layer. In other words, metal ion implantation is at an energy such that the doped metal ion is within the amorphous layer. Examples of dosages of the metal ion include dosages from about 1×10¹⁰ atom/cm² to approximately 1×10¹⁷ atom/cm² at doping energies of from approximately 1 keV to 1000 keV.

The doped amorphous layer, e.g., the amorphous layer doped with a metal ion, is annealed by any suitable technique to crystallize the amorphous layer. In a preferred embodiment, annealing is by laser annealing at an energy density of 50 to 3000 mJ/cm², alternatively 600 mJ/cm² to 1500 mJ/cm². In another example, energies of approximately 600 to 700 mJ/cm² can be applied by pulsing a laser having a spot size of approximately 25 mm². Some alternative parameters for laser annealing include a Full Width Half Maximum (FWHM) of pulse approximately 10 to 50 ns, a spot size more than 1 μm×1 μm˜30 mm×30 mm, and a wave length of laser (λ) of approximately 200 to 800 nm.

Annealing results in a layer of crystallized grains in the amorphous layer. For example, annealing can result in a layer of crystallized silicon grains, or essentially pure silicon, on a substrate material. Metal silicides reside at the intersection of the grains, e.g. at the grain boundaries. The metal silicide atoms extend from a surface of the crystalline layer into the interior of the structure. Most preferably, the metal silicide atoms are at the triple point intersections of grains.

In exemplary embodiments, the metal silicide nanowires 214 have a diameter of about 0.1 to 100 nm, alternatively 1 to 10 nm, and a length from the surface to the interior position of about 0.1 to 1000 nm, alternatively, 10 to 50 nm.

Structures comprising a silicon-based substrate with a silicon-based material layer on a first surface, the silicon-based material layer including a plurality of crystal grains in the silicon-based material and metal silicide located within the silicon-based material layer at grain boundaries between the plurality of crystal grains, can be used in electronic device applications. Exemplary electronic device applications include filed emitters and devices incorporating field emitters or arrays of field emitters, such as imagers and displays, and semiconductor memory devices and devices incorporating semiconductor memory devices, such as phase change memory devices.

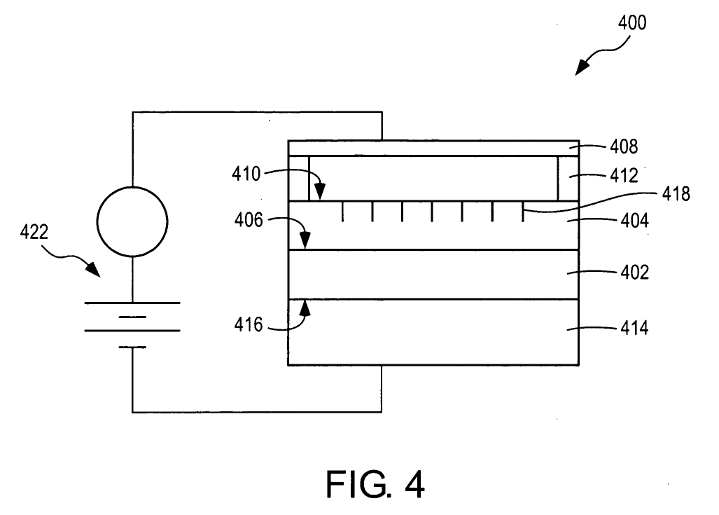

FIG. 4 shows a schematic representation of an exemplary field emitter device. The exemplary field emitter device 400 includes a silicon-based substrate 402, a silicon-based material layer 404 in direct contact with a first side 406 of the silicon-based substrate 402, a first electrode 408 spaced apart from a surface 410 of the silicon-based material layer 404 by a spacer 412, and a second electrode 414 on a second side 416 of the silicon-based substrate 402. The silicon-based material layer 404 includes a plurality of crystal grains in a silicon-based material and metal silicide 418, the metal silicide 418 located within the silicon-based material layer 404 at grain-boundaries between the plurality of crystal grains and the metal silicide 418 is arranged in a continuous electrical conduction path along any one of the grain-boundaries from the surface 410 of the silicon-based material layer 404 to an interior position within the silicon-based material layer 404. The exemplary field emitter 400 also includes a power source 422 electrically connected between the first electrode 408 and the second electrode 414.

A plurality of field emitters based on the devices and methods disclosed herein can be incorporated into field emission devices, such as consumer electronics, displays, imaging devices for purposes such as medical and security, and industrial devices such as diagnostic or quality control imagers. In an exemplary embodiment, the plurality of field emitters are arranged within the field emission device to be individually electrically addressable to field emit an electron. A controller can be electrically arranged to provide power to the plurality of field emitters to provide the necessary electric field to produce field emission. In another exemplary embodiment, the field emission devices are formed to be individually electrically addressable to field emit an electron by patterning techniques to form a matrix or array. For example, a patterned mask in the metal ion implantation portion of the methods disclosed herein can be used to preferentially ion implant the metal ion in addressable regions of the amorphous layer. Subsequent to annealing and crystallizing, the formed metal silicide nanowires are placed in electrical contact with correspondingly patterned electrodes.

The present invention can be more clearly understood with referring to the following examples. It should be understood that the following examples are not intended to restrict the scope of the present invention in any manner.

### EXAMPLE 1

Si ions are implanted on Si substrates with 50 keV of energy and 2×10¹⁵ atoms/cm² of dose, thereby forming an amorphous Si layer on the Si substrates with a predetermined thickness. Then, Ni ions are implanted on the amorphous Si layer with 25keV of energy and 5×10¹⁵ atoms/cm² of dose. The samples having implanted Ni ions are loaded into a vacuum chamber, and the samples are annealed using an excimer laser beam with the chamber maintained with about 10⁻³ torr of vacuum. One of the samples is annealed in a laser beam of 300 mJ/cm² and the other is annealed in a laser beam of 300 mJ/cm². The laser used in the example is a KrF excimer laser beam.

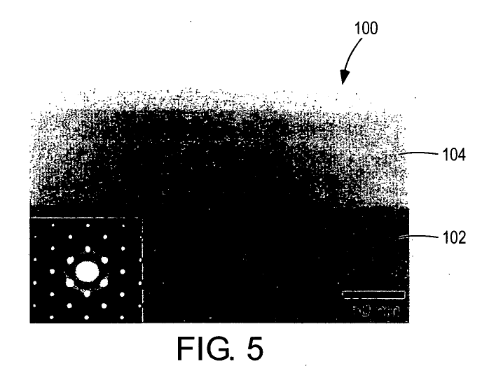

FIG. 5 is a micrograph 100 from a transmission electron microscope taken at 200 keV on the sample after Ni ion implantation and before Laser annealing in the Example 1. The sample in the micrograph 100 shows a silicon substrate 102 with an amorphous silicon layer 104. Nickel ions implanted to the amorphous layer 104, are not visible in FIG. 5. The silicon substrate 102 is polycrystalline and the amorphous layer 104 is formed by silicon implantation at a desired level.

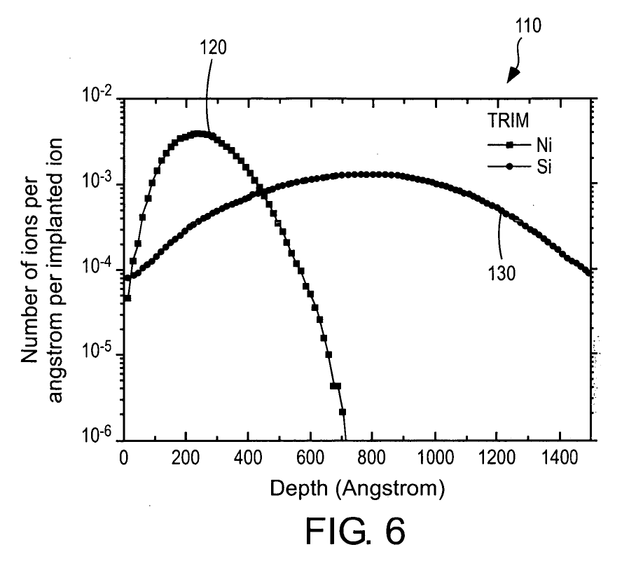

FIG. 6 is a TRIM simulation data showing number of ions per angstrom per implanted ion as a function of depth (in angstroms) for the sample shown in FIG. 5. In FIG. 6, both the number of nickel ions per angstrom per implanted ion 120 and the number of silicon ions per angstrom per implanted ion 130 are shown. From FIG. 6, it is seen that the sample in FIG. 5 has silicon ions implanted to a depth of greater than 1500 angstroms and nickel ions implanted to a depth of about 700 angstroms and.

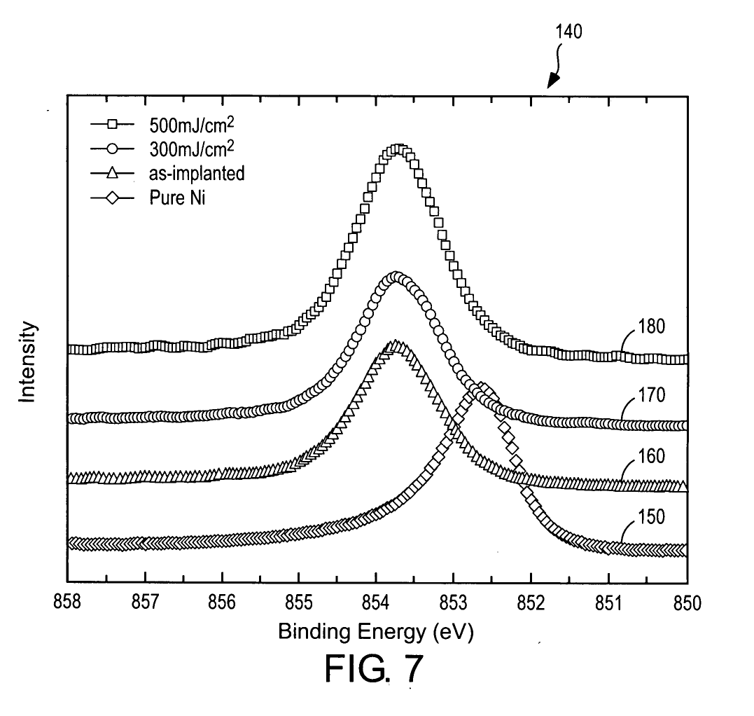

FIG. 7 illustrates x-ray photon spectroscopy (XPS) graphs on the samples in Example 1 and a sample of pure nickel. In the FIG. 7 graph 140, intensity as a function of binding energy (eV) is shown for a pure nickel sample 150, sample with implanted nickel ions taken in the as-implanted condition 160, sample with implanted nickel ions taken after laser annealing at 300 mJ/cm² 170, and sample with implanted nickel ions taken after laser annealing at 500 mJ/cm² 180. In the case of a pure Ni sample, Ni 2p peak is shown at 852.61 eV, but in the case of the rest of the samples, Ni 2p peak is shown at 853.71 eV. The shift in the peak between the pure nickel sample 150 and the implanted sample 160 and the implanted and annealed samples 170, 180 indicates that the implanted metal ion has formed metal silicide, e.g., nickel silicide. The results show that metal silicide is formed by the reaction of Ni and Si. That is, by the kinetic energy of the implanted Ni ions right after the Ni ions are implanted, the metal silicide is formed.

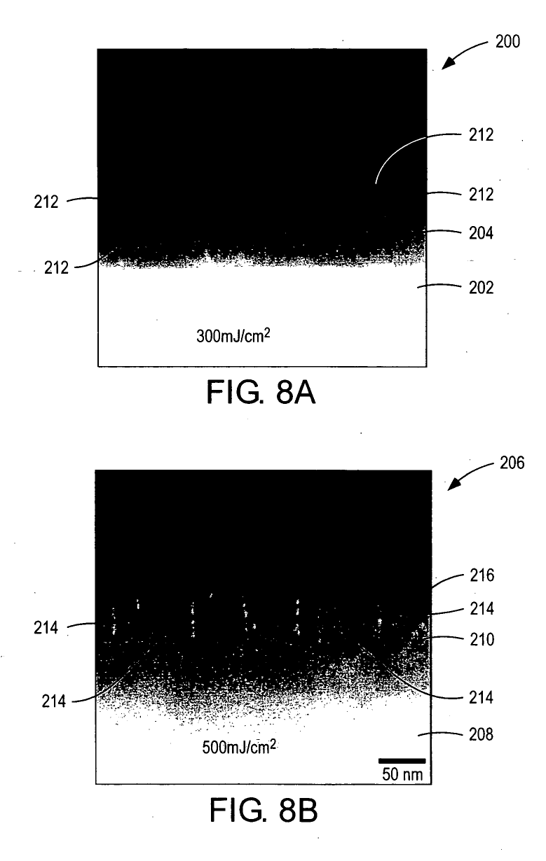

FIGS. 8A and 8B show scanning transmission electron microscope (STEM) results for the samples from Example 1. The micrographs were taken at 200 keV. FIG. 8A 200 shows a single crystal silicon substrate 202 with a polycrystalline silicon layer 204 formed by Si implantation (energy: 50 keV, does: 2×10¹⁵/cm²), Ni implantation (energy: 25 keV, does: 5×10¹⁵/cm²) and laser annealing (300 mJ/cm²). FIG. 8B 206 shows a single crystal silicon substrate 208 with a polycrystalline silicon layer 210 formed by Si implantation (energy: 50 keV, does: 2×10¹⁵/cm²), Ni implantation (energy: 25 keV, does: 5×10¹⁵/cm²) and laser annealing (500 mJ/cm²). Initially, Si and Ni implantation into the Si substrate results in the formation of a thick amorphous Si layer on top of the Si substrate. A representative amorphous layer is >80 nm. The amorphous Si layer can be transformed to polycrystalline Si after laser annealing.

In FIG. 8A, numerous silicide nanowires 212 are shown in the polycrystalline silicon layer 204. These silicide nanowires 212 are loosely organized along the grain boundaries of the grains forming the polycrystalline silicon layer 204.

In FIG. 8B, numerous silicide nanowires 214 are shown in the polycrystalline silicon layer 210. These silicide nanowires 214 are strongly correlated along the grain boundaries of the grains forming the polycrystalline silicon layer 210. Here, the higher energy density for the laser annealing step results in more of the metal ions migrating to the grain boundaries. In addition, once at the grain boundaries the metal ions continue to migrate towards the triple point within the polycrystalline silicon layer 210.

In FIG. 8B, the metal silicide nanowires 214 located at the grain boundaries are arranged in a continuous electrical conduction path along the grain boundaries from a surface 216 of the polycrystalline silicon layer 210 to an interior position within the polycrystalline silicon layer 210 or within the single crystal silicon substrate 208.

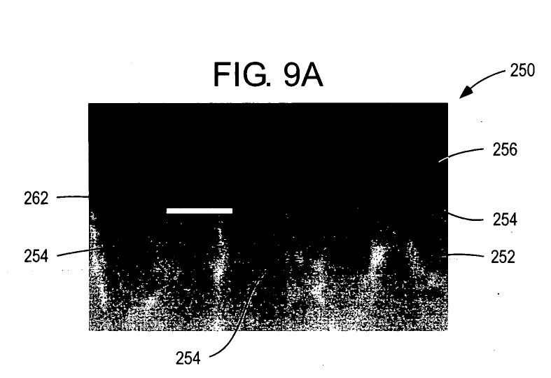

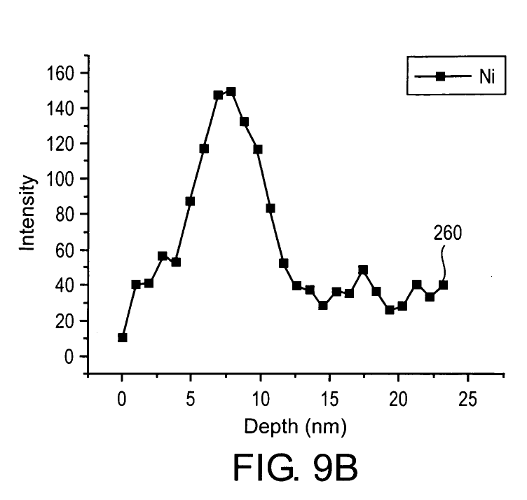

FIGS. 9A and 9B show results of energy dispersive x-ray spectroscopy experiments on the sample from Example 1. The micrograph 250 was taken at 200 keV. The cross sectional STEM image in FIG. 9A shows a polycrystalline silicon layer 252 formed by Si implantation (energy: 50 keV, does: 2×10¹⁵/cm²), Ni implantation (energy: 25 keV, does: 5×10¹⁵/cm²), and laser annealing (300 mJ/cm²) on single crystal silicon substrate (not shown). Embedded within the polycrystalline silicon layer 252 are numerous silicide nanowires 254 formed at the grain boundaries of the polycrystalline silicon layer 252 and extending from a surface 256 of the polycrystalline silicon layer 252 into the interior of the polycrystalline silicon layer 252. In the EDX graph of FIG. 9B, the intensity of the nickel response is graphed as a function of position. Illustrated in FIG. 9B is the results for nickel 260 taken as a function of position corresponding to positions along the line 262 in FIG. 9A. The results for nickel 260 indicate that the nickel ion, and thus the nickel silicide, is predominantly located at the silicide nanowire in the grain boundary position which is crossed by the line 262, with a lesser instance of nickel located outside the silicide nanowire. Further, the EDX results strongly reveal that nanowires include Ni atoms. In other words, the EDX results support the main composition of nanowire is Ni.

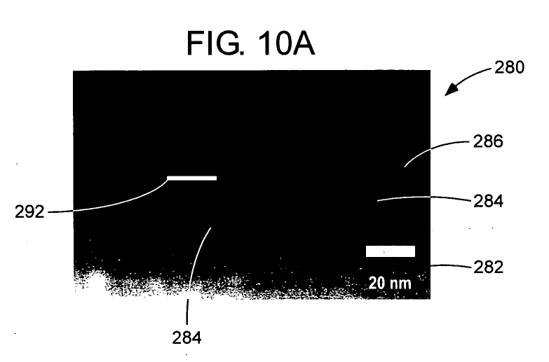

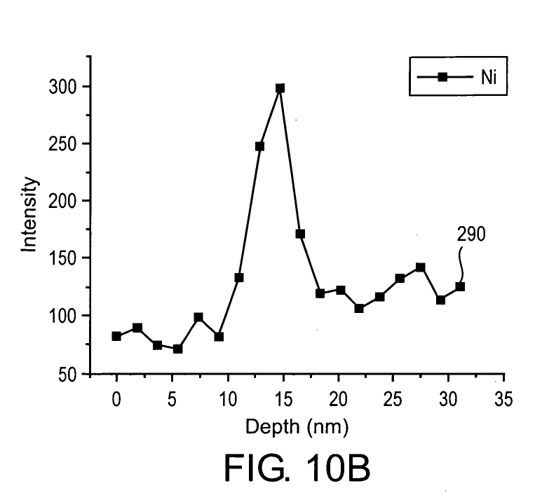

FIGS. 10A and 10B show results of energy dispersive x-ray spectroscopy experiments on the sample from Example 1. The micrograph 280 was taken at 200 keV. The cross sectional STEM image in FIG. 10A shows a polycrystalline silicon layer 282 formed by Si implantation (energy: 50 keV, does: 2×10¹⁵/cm²), Ni implantation (energy: 25 keV, does: 5×10¹⁵/cm²) and laser annealing (500 mJ/cm²) on single crystal silicon substrate (not shown). Embedded within the polycrystalline silicon layer 282 are several silicide nanowires 284 formed at the grain boundaries of the polycrystalline silicon layer 282 and extending from a surface 286 of the polycrystalline silicon layer 282 into the interior of the polycrystalline silicon layer 282. In the EDX graph of FIG. 10B, the intensity of the nickel response is graphed as function of position. Illustrated in FIG. 10B is the results for nickel 290 taken as a function of position corresponding to positions along the line 292 in FIG. 10A. The results for nickel 290 indicate that the nickel ion, and thus the nickel silicide, is predominantly located at the silicide nanowire in the grain boundary position which is crossed by the line 292, with a lesser instance of nickel located outside the silicide nanowire.

### EXAMPLE 2

Si ions are implanted on a Si substrate with 50 keV of energy and 2×10¹⁵ atoms/cm² of dose, thereby forming an amorphous Si layer on the Si substrate with a predetermined thickness. Then, Ni ions are implanted on the amorphous Si layer with 25 keV of energy and 5×10¹⁵ atoms/cm² of dose. The sample having implanted Ni ions is loaded into a vacuum chamber, and the sample is annealed using an excimer laser beam with the chamber maintained with about 10⁻³ torr of vacuum. The laser used in the example is a KrF excimer laser beam, and the energy density of the laser beam is 700 mJ/cm² for annealing.

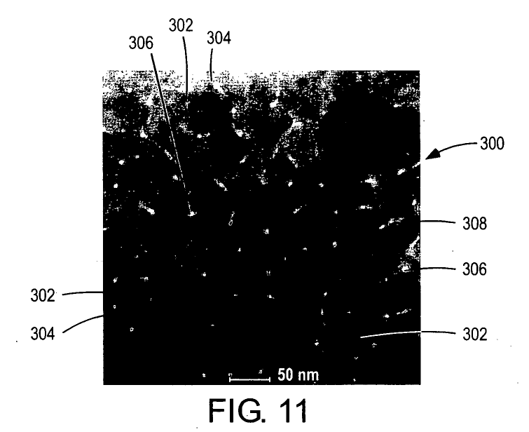

FIG. 11 is a plan STEM image 300 for the sample of Example 2. In FIG. 11, the amorphous layer has crystallized into a plurality of grains 302 separated one from the other by grain boundaries 304. At this energy density and for the silicon and nickel system, metal silicide has essentially completely agglomerated at the triple point 306 of the grain boundaries. In the FIG. 11 micrograph, the grain boundaries can still be observed, but the lighter regions 308 in the grain boundaries is due to the phase contrast and not a result of metal silicide in the grain boundary.

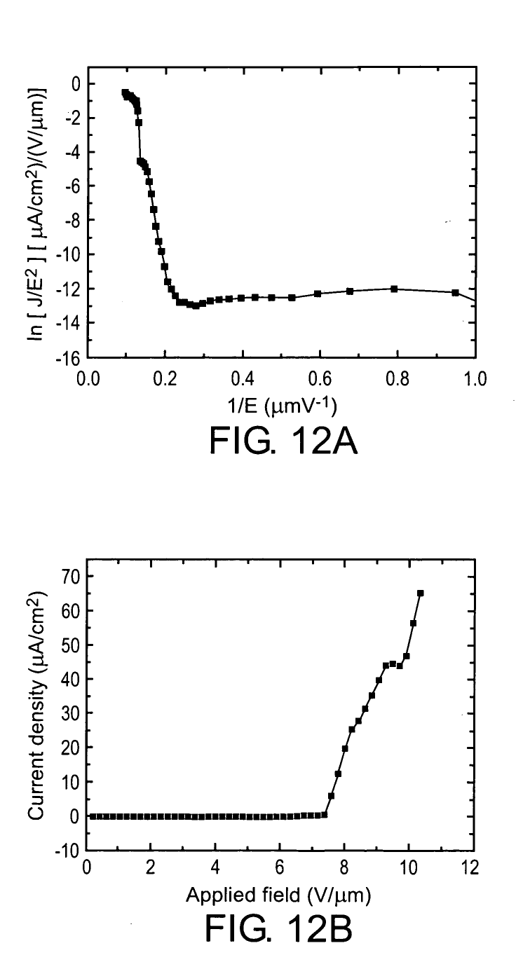

Then, Fowler-Nordheim graph is measured using the prepared sample and shown in FIGS. 12A and 12B. The device structure for measuring the graph is the same with the field emitter structure shown in FIG. 4. As an electrode, ITO and aluminium is used. The spacing gap between upper electrode and the surface containing metal silicide nanowire is 256 μm. The results illustrated in FIGS. 12A and 12B indicate a low noise level (FIG. 12A) and an exponential increase in current density at increasing applied field (FIG. 12B) consistent with good field emission properties.

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

What is claimed is:

1. A method for forming a silicon-based material layer, the method comprising:
forming an amorphous layer on a silicon-based substrate;
doping at least a region of the amorphous layer with a metal ion; and
crystallizing the amorphous layer to form a plurality of crystal grains,
wherein a grain boundary is between adjacent crystal grains and metal silicide is formed at the grain boundary.

2. The method of claim 1, wherein forming the amorphous layer includes implanting an ion of a Group IV element of the periodic table in the silicon-based substrate.

3. The method of claim 2, wherein the Group IV element of the periodic table is selected from the group consisting of Si, Ge, Sn, and Pb.

4. The method of claim 1, wherein the metal ion is an ion of a metal selected from the group consisting of Ag, Au, Al, Cu, Cr, Co, Ni, Ti, Sb, V, Mo, Ta, Nb, Ru, W, Pt, Pd, Zn, and Mg.

5. The method of claim 1, wherein doping occurs at a doping energy of 1 keV to 1000 keV and at a doping amount of 1×10¹⁰ atom/cm² to 1×10¹⁷ atom/cm².

6. The method of claim 1, wherein crystallizing includes annealing the doped amorphous layer.

7. The method of claim 6, wherein annealing includes laser annealing at an energy density of 50 to 3000 mJ/cm².

8. The method of claim 1, wherein the silicon-based substrate is Si, SiGe, SiC, SiO₂, or SiO₂ with a layer of Si, SiGe or SiC on the first surface, MgO with a layer of Si, SiGe or SiC on the first surface, ITO with a layer of Si, SiGe or SiC on the first surface, crystalline Si with a layer of Si, SiGe or SiC on the first surface or amorphous silicon with a layer of Si, SiGe or SiC on the first surface.

9. The method of claim 1, wherein metal silicide located at the grain boundary is arranged in a continuous electrical conduction path along the grain boundary from a surface of the crystallized amorphous layer to an interior position within the crystallized amorphous layer or the silicon-based substrate.

10. The method of claim 9, wherein the metal silicide forms a nanowire with a diameter of about 0.1 to 100 nm and a length from the surface to the interior position of about 0.1 to 1000 nm.

11. The method of claim 1, wherein the metal silicide formed at the grain boundary defines a nanowire.

12. The method of claim 11, wherein the nanowire has a diameter of about 0.1 to 100 nm and a length of about 0.1 to 1000 nm.

13. The method of claim 1, wherein the metal silicide is at a triple point of the grain boundary.

14. A silicon-based material layer, comprising:
a plurality of crystal grains in a silicon-based material; and
metal silicide,
wherein the metal silicide is located within the silicon-based material layer at grain-boundaries between the plurality of crystal grains.

15. The silicon-based material layer of claim 14, wherein the metal silicide located at the grain-boundaries are arranged in a continuous electrical conduction path along any one of the grain-boundaries from a surface of the silicon-based material layer to an interior position within the silicon-based material layer.

16. The silicon-based material layer of claim 15, wherein the metal silicide in the continuous electrical conduction path forms a nanowire with a diameter of about 0.1 to 100 nm and a length from the surface to the interior position of about 0.1 to 1000 nm.

17. The silicon-based material layer of claim 14, wherein the metal of the metal silicide is selected from the group consisting of Ag, Au, Al, Cu, Cr, Co, Ni, Ti, Sb, V, Mo, Ta, Nb, Ru, W, Pt, Pd, Zn, and Mg.

18. The silicon-based material layer of claim 14, wherein the metal silicide is at a triple point of the grain boundary.

19. The silicon-based material layer of claim 14, wherein the metal silicide includes 1×10¹⁰ to 1×10¹⁷ atoms/cm² of metal ions.

20. A structure, comprising:
a silicon-based substrate; and
the silicon-based material layer according to claim 14 on a first surface of the substrate.

21. The structure of claim 20, wherein the silicon-based substrate is Si, SiGe, SiC, SiO₂, or SiO₂ with a layer of Si, SiGe or SiC on the first surface, MgO with a layer of Si, SiGe or SiC on the first surface, ITO with a layer of Si, SiGe or SiC on the first surface, crystalline Si with a layer of Si, SiGe or SiC on the first surface or amorphous silicon with a layer of Si, SiGe or SiC on the first surface.

22. A semiconductor memory device having the structure of claim 21.

23. A field emitter, comprising:
a silicon-based substrate;
a silicon-based material layer in direct contact with a first side of the silicon-based substrate, wherein the silicon-based material layer includes a plurality of crystal grains in a silicon-based material, and metal silicide, the metal silicide located within the silicon-based material layer at grain-boundaries between the plurality of crystal grains and the metal silicide is arranged in a continuous electrical conduction path along any one of the grain-boundaries from a surface of the silicon-based material layer to an interior position within the silicon-based material layer;
a first electrode spaced apart from the surface of the silicon-based material layer by a spacer; and
a second electrode on a second side of the silicon-based substrate.

24. The field emitter of claim 23, comprising a power source electrically connected between the first electrode and the second electrode.

25. The field emitter of claim 23, wherein the silicon-based substrate is Si, SiGe, SiC, SiO₂, or SiO₂ with a layer of Si, SiGe or SiC on the first surface, MgO with a layer of Si, SiGe or SiC on the first surface, ITO with a layer of Si, SiGe or SiC on the first surface, crystalline Si with a layer of Si, SiGe or SiC on the first surface or amorphous silicon with a layer of Si, SiGe or SiC on the first surface.

26. The field emitter of claim 23, wherein the metal silicide in the continuous electrical conduction path forms a nanowire with a diameter of about 0.1 to 100 nm and a length from the surface to the interior position of about 0.1 to 1000 nm

27. The field emitter of claim 23, wherein the metal silicide is at a triple point of the grain boundary.

28. A field emission display comprising a plurality of field emitters of claim 23.

29. The field emission display of claim 28, wherein the plurality of field emitters are individually electrically addressable to field emit an electron.
